(19) United States
(12) Patent Application Publication
(10) Pub. No.: US 2025/0174437 A1
(43) Pub. Date: May 29, 2025

(54) CONTROL DEVICE AND METHOD FOR ACTUATING AN IMPEDANCE MATCHING CIRCUIT FOR A PLASMA GENERATION SYSTEM AND PLASMA GENERATION SYSTEM OF THIS KIND

(71) Applicant: TRUMPF Hüttinger GmbH + Co. KG, Freiburg (DE)

(72) Inventor: Florian A. Maier, Pfaffenweiler (DE)

(21) Appl. No.: 19/038,720

(22) Filed: Jan. 28, 2025

Related U.S. Application Data
(63) Continuation of application No. PCT/EP2023/070886, filed on Jul. 27, 2023.

(30) Foreign Application Priority Data
Jul. 29, 2022 (DE) 102022119157.5

(51) Int. Cl. H01J 37/32

(52) U.S. Cl. CPC H01J 37/32183; H01J 37/32146

(57) ABSTRACT

A control device for actuating an impedance matching circuit for a plasma generation system having an input terminal and an output terminal for connection between an RF generator and a load is provided. The control device is configured to use a predeterminable operating frequency of the RF generator, a predetermined target power of the RF generator, and model parameters of the RF generator to determine a target impedance value for the input terminal of the impedance matching circuit. The target impedance value has a value different to a nominal impedance in order to increase a characteristic operating value of the RF generator for the predeterminable operating frequency and the predeterminable target power.

### CROSS REFERENCE TO RELATED APPLICATIONS

This application is a continuation of International Application No. PCT/EP2023/070886 (WO 2024/023244 A1), filed on Jul. 27, 2023, and claims benefit to German Patent Application No. DE 10 2022 119 157.5, filed on Jul. 29, 2022. The aforementioned applications are hereby incorporated by reference herein.

### FIELD

Embodiments of the present invention relate to a control device for actuating an impedance matching circuit for a plasma generation system, to a method for actuating an impedance matching circuit for a plasma generation system, and to a plasma generation system of this kind having a control device of this kind.

### BACKGROUND

The surface treatment of workpieces using plasma and gas lasers are industrial processes in which a plasma is generated, in particular in a plasma chamber, using direct current or a high-frequency alternating signal at an operating frequency in the range of several 10 kHz up to the GHz range.

The plasma chamber can be connected to a radio-frequency generator (RF generator) via other electronic components, such as coils, capacitors, lines or transformers. These other components may function as resonant circuits, filters or impedance matching systems.

The problem with the plasma process is that the electrical load impedance of the plasma in the plasma chamber that arises during the process depends on the conditions in the plasma chamber and can vary greatly. In particular, the properties of the workpiece, electrodes and gas ratios are taken into account. The special feature of such greatly varying loads may also be that these load changes occur faster than controlled impedance matching can make a load adjustment. In particular, a load change can also occur within a period of the fundamental wave, that is to say the RF power signal that operates the plasma. In this case, not only power is reflected in the fundamental wave, but also power components in so-called harmonics.

Radio-frequency generators have a limited operating range with respect to the impedance of the connected electrical load (=consumer). If the load impedance leaves a permissible range, the RF generator may be damaged or even destroyed. In most cases, this is due to the reflected power, which can damage the generator if, for example, the reflected power, the voltage or the reflected energy becomes too high for the RF generator.

For this reason, an impedance matching circuit (matchbox) which transforms the load impedance to a nominal impedance of the generator output is usually required.

Various impedance matching circuits are known. Either the impedance matching circuits are fixed and have a predetermined transformation effect, that is to say they consist of electrical components, in particular coils and capacitors, which are not changed during operation. This is expedient when the operation is always constant, such as in the case of a gas laser, for example. Furthermore, impedance matching circuits in which at least some of the components of the impedance matching circuits are mechanically variable are known. For example, motor-operated variable capacitors are known, the capacitance value of which can be changed by changing the arrangement of the capacitor plates relative to one another.

Three impedance ranges can be assigned to a plasma at first glance. Before ignition, there are impedances with a relatively high real part. Impedances with a relatively lower real part are present during normal operation, that is to say when operating with plasma as intended. Relatively small impedance values may occur in the case of unwanted local discharges (arcs) or plasma fluctuations. In addition to these three identified impedance ranges, other special states with other assigned impedance values may arise. If the load impedance changes abruptly and the load impedance and thus also the transformed load impedance leaves a permissible impedance range, the RF generator or else transmission devices between the RF generator and the plasma chamber may be damaged. There are also stable states of the plasma that are not desired. For example, in a plasma chamber, a stable plasma can form in an area in which it is not at all desired, for example in a peripheral area instead of at the target.

For example, an impedance matching circuit is described in DE 10 2009 001 355 A1.

It is also known that plasma processes require relatively high power, often one or more kW, and/or energy, which is becoming increasingly important nowadays.

An RF generator and an impedance matching circuit each operate with varying efficiency depending on several parameters. As power and/or energy in the plasma process increases, efficiency plays an increasingly important role.

### SUMMARY

Embodiments of the present invention provide a control device for actuating an impedance matching circuit for a plasma generation system having an input terminal and an output terminal for connection between an RF generator and a load. The control device is configured to use a predeterminable operating frequency of the RF generator, a predetermined target power of the RF generator, and model parameters of the RF generator to determine a target impedance value for the input terminal of the impedance matching circuit. The target impedance value has a value different to a nominal impedance in order to increase a characteristic operating value of the RF generator for the predeterminable operating frequency and the predeterminable target power.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows an exemplary embodiment of a plasma generation system comprising an RF generator, an impedance matching circuit, a control device and a plasma chamber;

FIG. 2A and FIG. 2B show various exemplary embodiments of the impedance matching circuit;

FIG. 3 shows an exemplary embodiment of a first and/or second measuring unit to contactlessly measure a voltage and a current;

FIG. 4 shows a Smith chart illustrating how the RF generator changes from maximum power to maximum efficiency depending on the target impedance value;

FIG. 5 shows a graph showing a profile of the efficiency for certain target powers in relation to the required target impedance values; and

FIG. 6 shows a flowchart describing a method for actuating the impedance matching circuit.

### DETAILED DESCRIPTION

Embodiments of the present invention can establish a low-loss, energy-saving plasma process.

The control device is used to actuate an impedance matching circuit for a plasma generation system. The impedance matching circuit comprises an input terminal and an output terminal and can be connected between an RF generator and a load. In particular, the load may be at least one electrode on which a plasma, in particular in a plasma chamber, is generated.

The control device is designed to use:
a) a predeterminable operating frequency of the RF generator;
b) a predeterminable target power of the RF generator; and
c) model parameters of the RF generator;
to determine a target impedance value for the input terminal of the impedance matching circuit, wherein the target impedance value has a value different to a nominal impedance of the RF generator in order to thereby increase a characteristic operating value of the RF generator for the predeterminable operating frequency and the predeterminable target power. The operating characteristic value of the RF generator is preferably the efficiency of the RF generator. In this case, the control device may be designed to receive the predeterminable operating frequency, the predeterminable target power and the model parameters of the RF generator and/or have them internally stored and/or have access to them in another way. This means that it can receive them, for example, via an interface, for example an electronic data interface. Said control device may have stored them in an internal electronic data memory, for example. It may, for example, determine them itself from other sources or data or a combination thereof.

It is preferred that the target impedance value for the input terminal of the impedance matching circuit is variable. The RF generator can be connected to the input terminal. If said target impedance value differs from the nominal impedance, the RF generator is mismatched with the input terminal. The RF generator is operated at a different operating point to the one at which it can deliver the maximum power. Instead, an operating point is set at which the efficiency with which the RF generator can be operated is increased. Due to the increased efficiency, the energy consumption of the RF generator is significantly reduced and the plasma process is more energy-efficient. Research has shown that a plasma process rarely requires the maximum power of the RF generator that it can provide. Such a maximum power can be provided by the RF generator upon adjustment, that is to say when the target impedance value is set to the nominal impedance of the RF generator. In this operating state, however, the RF generator also requires the most energy.

The operating frequency of the RF generator is preferably freely adjustable. The RF generator is designed, in particular, in plasma processes to generate and output RF signals which are in the range of preferably 1 MHz to 200 MHz, preferably in the range of 3 MHz to 100 MHz and further preferably in the range of 12 MHz to 50 MHz. The RF generator is further preferably designed to generate RF signals with frequencies of 13.56 MHz, 27 MHz and/or 40 MHz.

In principle, it is conceivable that the RF generator can be designed to modulate the RF signal.

The term “efficiency” is preferably understood to mean the power (in particular active power) which is coupled into the load in relation to the power (in particular active power) taken up by the generator.

In a preferred embodiment, the operating characteristic value comprises one or more of the following characteristics of the RF generator:
a) efficiency;
b) temperature, in particular the limitation to a maximum permissible temperature, in certain components, for example transistors, capacitances, inductances, couplers, matching circuits;
c) voltage, in particular the limitation to a maximum permissible voltage, in certain components, for example transistors, capacitances, inductances, couplers, matching circuits;
d) current, in particular the limitation to a maximum permissible current, in certain components, for example transistors, capacitances, inductances, couplers, matching circuits.

The characteristics of the RF generator, which refer to temperature, voltage and current, may also influence the efficiency. Limiting to a maximum permissible temperature may correlate to a maximum permissible energy consumption. Similarly, limiting to a maximum permissible voltage or to a maximum permissible current may correlate to a maximum permissible energy consumption.

In a preferred embodiment, the target power, which is adjustable, is an active power. The target power is rarely also the power that is output to the load because an impedance matching circuit may exhibit active power losses, which may also depend on the setting of the impedance matching circuit. However, this is less of an obstacle to the efficiency of the plasma process because the active power losses in the impedance matching circuit are reproducible. This ensures that a plasma process that works for a certain target power will also work in the future.

In another preferred embodiment, the control device is designed to actuate the impedance matching circuit in such a way that it sets the impedance of the input terminal of the impedance matching circuit to the target impedance value. This can be carried out before the RF generator is activated or during operation of the RF generator. The control device is also designed to continuously adjust, that is to say to change, the target impedance values during operation of the RF generator.

In another preferred embodiment, the nominal impedance is 50 ohms. This is a standardized magnitude and most cables or connectors are designed for this. The output impedance of the RF generator is usually designed for the nominal impedance so that there are no reflections with the components.

In another preferred embodiment, the control device is designed to select the target impedance value for which the efficiency is improved compared to an efficiency for the nominal impedance. The target impedance value for which the efficiency is improved by at least 5%, 10%, 15%, 20%, 25%, 30%, 35%, 40%, or at least 45% compared to the efficiency for the nominal impedance is preferably selected.

In another preferred embodiment, the model parameters of the RF generator include corresponding target impedance values for various predeterminable target powers. For the respective target impedance values, the efficiency reaches its maximum or is not more than 10% away from its maximum. For example, the model parameters may be stored in a look-up table. Corresponding model parameters are available for the respective different operating frequencies. There is preferably a separate look-up table for each operating frequency or a look-up table is valid for one or more operating frequencies or a frequency range. It is also conceivable that a look-up table is calculated using a corresponding conversion factor (value or function), so that this look-up table can be used for different operating frequencies depending on the conversion factor. This can reduce the storage space. The control device preferably comprises a storage device to store the look-up table. Corresponding target impedance values, for which the efficiency reaches its maximum or is at most 10% away from its maximum, for different target powers are further preferably stored in the look-up table.

In another preferred embodiment, the various target powers are on a curve or a set of curves. The maximum efficiency is preferably achieved when a curve is used. The target powers may preferably be 10% or less away from the maximum efficiency when a set of curves is used. This makes it possible for the user to visualize the plasma process, so that they are supported in setting the plasma process, in particular the setting according to the above-mentioned criteria becomes possible for them in the first place.

In another preferred embodiment, the control device is designed, for adjacent target powers on the curve or set of curves, to store those target impedance values which when selected in succession require a minimum mechanical adjustment of the impedance matching circuit. For example, the target powers can be stored at a resolution of one tenth (0.1). In this case, adjacent target powers would be, for example, 49 dBm and 49.1 dBm. The target impedance values for which the correspondingly increased efficiency is achieved could then be selected, with the mechanical adjustment (mechanical travel) of capacitors and/or inductances being kept to a minimum. This can protect the motor and/or the transmission of the impedance matching circuit.

In another preferred embodiment, the control device is designed to additionally take into account the model parameters of a cable impedance of a cable connection between the RF generator and the impedance matching circuit. The cable impedance is also dependent on frequency, so different cable impedances are taken into account for different operating frequencies. This enables the efficiency of the RF generator to be set more accurately.

In another preferred embodiment, the control device is designed to load the cable impedance from a storage device. In this case, for example, the cable impedance could be stored in the same storage device in which the look-up table is also stored.

In another preferred embodiment, the control device is designed to calculate the cable impedance by means of a first and second measuring unit. The first measuring unit can be arranged between the RF generator and the cable connection. The second measuring unit can be arranged between the cable connection and the impedance matching circuit or between the impedance matching circuit and the load. The first measuring unit can therefore be arranged in particular in the region of the output terminal of the RF generator and the second measuring unit can therefore be arranged in particular in the region of the input terminal or the output terminal of the impedance matching circuit. The control device is therefore designed to determine the current cable impedance of the cable connection before the RF generator is activated and/or to detect a change in the cable impedance of the cable connection during operation. The correct values for the cable impedance are thus automatically used when another cable connection is connected. In the event that the second measuring unit is arranged downstream of the impedance matching circuit and upstream of the load, the model parameters, in particular the Z parameters, of the impedance matching circuit must still be taken into account. However, these are known in each case for the current state of the impedance matching circuit. The cable impedance may also be referred to as a model parameter of the cable connection. It can thus be said that the control device is also designed to take into account the model parameters for the cable connection.

In another preferred embodiment, the control device comprises different model parameters for different operating frequencies of the RF generator.

In another preferred embodiment, the input terminal of the impedance matching circuit is arranged on the housing of the impedance matching circuit. In principle, however, it would also be conceivable for the RF generator to be able to be connected via a cable connection to the impedance matching circuit, wherein a first end of the cable connection can be connected to the RF generator, and wherein a second end of the cable connection can be connected to the impedance matching circuit, wherein the input terminal is arranged at the first end of the cable connection and thus at the RF generator. In this case, the input terminal is not arranged directly on the housing of the impedance matching circuit. This makes it clear that the cable connection can be taken into account concomitantly and the control device is set up to set a target impedance value that acts on the RF generator directly at the output of the RF generator.

In another preferred embodiment, the control device is designed, in pulsed operation of the RF generator in which pulses with different amplitudes and preferably also with pulse pauses are generated, to determine different target impedance values for the input terminal of the impedance matching circuit for the different pulses. This can maximize the efficiency.

In another preferred embodiment, the control device is designed to determine target impedance values for the input terminal of the impedance matching circuit, wherein the target impedance values are selected such that the RF generator can provide a corresponding target power for the entire envelope of a generated signal. This means that the power of the RF generator is sufficient to fully reproduce the amplitude of the generated signal. The RF generator should thus also be able to provide sufficient power for the peaks of the generated signal. In this case, the target impedance value should be selected in such a way that the RF generator can still generate the maximum power required.

The plasma generation system according to embodiments of the invention comprises a corresponding control device as described at the beginning. The plasma generation system furthermore comprises an RF generator and an impedance matching circuit. The output terminal of the RF generator is connected to the input terminal of the impedance matching circuit. An output terminal of the impedance matching circuit is preferably connected to a load, in particular at least one electrode in a plasma chamber.

In another embodiment, the impedance matching circuit is integrated into the RF generator. This has the advantage that the impedance matching circuit does not also have to take into account the cable impedance, which is preferably at 50 ohms. For example, the transformation of the transistor impedance, which is at 5 ohms, to the plasma impedance, which is preferably at 2 ohms, is easier to accomplish because the components of the impedance matching circuit (for example capacitors, inductances) need to be less significantly adjusted.

In another preferred embodiment, the control device is designed to take into account the cable impedance of the cable connection between the RF generator and the impedance matching circuit when determining the target impedance value at the input terminal of the impedance matching circuit. The cable impedance is preferably measured continuously (for example several times per second) so that, in the case of a changing cable impedance, the impedance matching circuit is adjusted during operation so that the desired target impedance value is still reached.

In another preferred embodiment, the plasma generation system comprises a first and a second measuring unit. The control device is designed to calculate the cable impedance of the cable connection between the RF generator and the impedance matching circuit by means of the first and second measuring unit. The first measuring unit is arranged between the RF generator and the cable connection. The first measuring unit is arranged closer to the RF generator and the second measuring unit is arranged closer to the impedance matching circuit. The second measuring unit is arranged between the cable connection and the impedance matching circuit or between the impedance matching circuit and the load.

In another preferred embodiment, the first measuring unit is a directional coupler. In addition or as an alternative, the second measuring unit is a directional coupler. In addition or as an alternative, the first measuring unit comprises a current sensor and a voltage sensor. In addition or as an alternative, the second measuring unit comprises a current sensor and a voltage sensor. These sensors can be used to calculate the cable impedance of the cable connection.

In another preferred embodiment, the voltage sensor of the first measuring unit comprises a capacitive voltage divider, wherein a first capacitance is formed by an electrically conductive ring or cylinder, through which the cable connection between the RF generator and the impedance matching circuit is routed. The current sensor of the first measuring unit comprises a coil arranged around the conductive ring or cylinder. This enables a compact design to be realized. In addition or as an alternative, the voltage sensor of the second measuring unit comprises a capacitive voltage divider, wherein a first capacitance is formed by an electrically conductive ring or cylinder. Either the cable connection between the RF generator and the impedance matching circuit or the cable connection between the impedance matching circuit and the load is routed through the cylinder. The current sensor of the second measuring unit comprises a coil arranged around the conductive ring or cylinder. This enables a compact design to be realized.

In another preferred embodiment, the control device is designed to change the power of the RF generator, with this being done by changing an input power of an amplifier of the RF generator and/or by changing a supply voltage of an amplifier of the RF generator. This enables the RF generator to be trimmed even more accurately for further improved efficiency.

In another preferred embodiment, the first cable connection comprises at least two cables connected in parallel in order to reduce the impedance of the cable connection. In this case, the ends of the two inner conductors are each electrically connected, in particular soldered, to one another. A 25 ohm cable would thus be created from two 50 ohm cables. In this case, the nominal impedance of the system would be 25 ohms. Thanks to this measure, a transition from a transistor impedance of the RF generator of approximately 5 ohms at the cable impedance of 25 ohms to the plasma impedance of approximately 2 ohms is less than from 5 ohms at the cable impedance of the standardized 50 ohms to the plasma impedance of approximately 2 ohms. This further reduces the losses.

In another preferred embodiment, the impedance matching circuit comprises one or more capacitances, wherein the value of at least one capacitance can be changed during operation. The change can be made by actuating a variable capacitor, in particular a variable vacuum capacitor, by means of a motor, in particular a stepper motor. A transmission is preferably also provided. Instead of a motor, it is also possible to use a switch, in particular in the form of a solid state switch, to switch capacitances on and/or off. In particular, multiple switched capacitances of this kind may be provided in order to be able to set multiple different capacitance values. In this case, the target impedance value can be set quickly, in particular more quickly than with a motor-driven capacitor adjustment, preferably in less than 100 ms, 50 ms, 10 ms or in less than 1 ms. This is useful when using a pulsed signal in order to be able to react quickly to different pulse levels.

The method according to embodiments of the invention is used to actuate an impedance matching circuit for a plasma generation system having an input terminal connected to an output terminal of an RF generator and an output terminal connected to the input of a load. The method is suitable for setting the input impedance at the input terminal with varying output impedance at the output terminal having the following method steps:
determining a target impedance value for the input terminal based on:
   a) a predeterminable operating frequency of the RF generator;
   b) a predetermined target power of the RF generator; and
   c) model parameters of the RF generator;
   wherein the target impedance value has a value different to the nominal impedance in order to increase a characteristic operating value of the RF generator, in particular the efficiency, for the predeterminable operating frequency and the predeterminable target power.

Exemplary embodiments of the invention are described below with reference to the drawings. The same objects have the same reference signs.

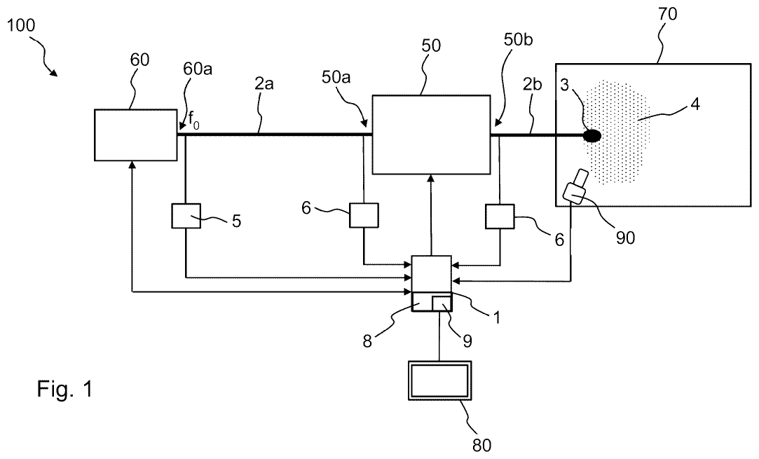

FIG. 1 shows a plasma generation system 100 which is used, among other things, for the surface treatment of workpieces.

The plasma generation system 100 comprises a control device 1, an impedance matching circuit 50, an RF generator 60 and a plasma chamber 70 as load. The RF generator 60 is electrically connected to the impedance matching circuit 50. This is achieved via a cable connection 2a, which is preferably a first cable connection 2a, in particular at least a first coaxial cable 2a. The first cable connection 2a is connected to an output terminal 60a of the RF generator 60 and to an input terminal 50a of the impedance matching circuit 50. The impedance matching circuit 50 is also electrically connected to the plasma chamber 70. This is preferably achieved via a further, in particular second, cable connection 2b, which is preferably a second coaxial cable 2b. The impedance matching circuit 50 is often arranged close to the plasma chamber 70, in particular at a distance of 10 cm or less than 10 cm, preferably arranged directly on said plasma chamber, so that the second cable connection 2b is also correspondingly short and has only a few mechanical parts, such as connectors and/or line connectors, for example. The second cable connection 2b is connected to an output terminal 50b of the impedance matching circuit 50 and to an input of the plasma chamber 70. The second cable connection 2b is preferably connected to an electrode within the plasma chamber 70.

The first cable connection 2a is longer than the second cable connection 2b. The first cable connection 2a is preferably longer than the second cable connection 2b by a factor of 2, 3, 4, 5, 6, 7 or at least by a factor of 8.

The first cable connection 2a may also comprise at least two cables connected in parallel in order to reduce the overall impedance of the cable connection. In this case, the ends of the two inner conductors are each electrically connected, in particular soldered, to one another. A 25 ohm cable would thus be created from two 50 ohm cables. As a result, a transition from a transistor impedance of the RF generator 60 of approximately 5 ohms at the cable impedance of 25 ohms to the plasma impedance of approximately 2 ohms is less. In this case, the nominal impedance would be 25 ohms.

The plasma generation system 100 preferably comprises an input and output device 80, which is preferably a screen, in particular a screen controllable by touch. A keyboard and/or a mouse and a monitor may also be regarded as an input and output device 80.

The plasma chamber 70 may be considered a consumer (load). Depending on the application, for example one or more electrodes 3 may be provided in the plasma chamber 70, at least one of which is connected to the second cable connection 2b. FIG. 1 uses dots to illustrate a plasma 4 within the plasma chamber 70.

The plasma generation system 100 preferably also comprises an optical device 90. The optical device 90 is further preferably arranged in the plasma chamber 70 and designed to visually detect the plasma 4 and thus the plasma state. The optical device 90 may be, for example, an optical conductor, such as a glass fibre. Although cameras can be used, they are often omitted for cost reasons. Furthermore, lenses and other protective glasses can quickly become cloudy due to the plasma 4.

The control device 1 is preferably a processor (for example a microcontroller) and/or a programmable logic module, for example an FPGA (field-programmable gate array).

The control device 1 is used to actuate the impedance matching circuit 50. The control device 1 is designed to use a predeterminable operating frequency of the RF generator 60, a predeterminable target power of the RF generator 60 and model parameters of the RF generator 60 to determine a target impedance value for the input terminal 50a, wherein the target impedance value has a value different to the nominal impedance (usually 50 ohms) in order to thereby increase a characteristic operating value of the RF generator 60, in particular to thereby increase the efficiency, for the predeterminable operating frequency and the predeterminable target power.

The model parameters of the RF generator 60 include corresponding target impedance values, for which the efficiency reaches its maximum or is at most 10% away from its maximum, for various predeterminable target powers. For example, these target powers can be entered by a user via the input and output device 80. They can also be stored in the control device 1 for a certain plasma process. If a user selects a certain plasma process, a target power stored for that plasma process is retrieved and a corresponding target impedance value is loaded.

A look-up table 9 in which corresponding target impedance values, for which the efficiency reaches its maximum or is at most 10% away from its maximum, are stored for different target powers is preferably stored in the storage device 8.

FIG. 1 shows the input terminal 50a of the impedance matching circuit 50 directly on the housing of the impedance matching circuit 50. In principle, it could also be present at the end of the first cable connection 2a at which the first cable connection 2a is connected to the RF generator 60. As a result, the cable impedance of the first cable connection 2a is also taken into account. In this case, the RF generator 60 directly sees the target impedance value, which is not distorted by the first cable connection 2a.

As already explained, it is preferred if the control device 1 is designed to additionally take into account the model parameters of a cable impedance of the first cable connection 2a between the RF generator 60 and the impedance matching circuit 50. The model parameters for the cable impedance can be stored in a storage device 8. Said model parameters are dependent on frequency and different cable impedances are loaded depending on the operating frequency of the RF generator 60.

The control device 1 could also be designed to calculate the cable impedance of the first cable connection by means of a first and second measuring unit 5, 6, wherein the first measuring unit 5 is arranged between the RF generator 60 and the first cable connection 2a and wherein the second measuring unit 6 is arranged between the first cable connection 2a and the impedance matching circuit 50 or between the impedance matching circuit 50 and the load 70. FIG. 1 shows a second measuring unit 6. In the event that the second measuring unit 6 is arranged between the impedance matching circuit 50 and the load 70, the control device 1 is designed to additionally take into account the model parameters of the impedance matching circuit 50.

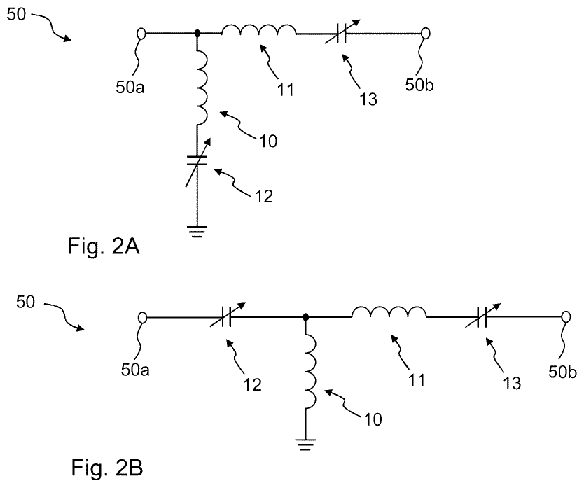

FIGS. 2A and 2B show various exemplary embodiments of the impedance matching circuit 50. In FIG. 2A, the impedance matching circuit 50 is L-shaped. In FIG. 2B, the impedance matching circuit 50 is T-shaped.

In FIG. 2A, the input terminal 50a of the impedance matching circuit 50 is connected to a first coil 10 (first inductance) and to a second coil 11 (second inductance). The first and second coils 10, 11 are connected by way of their first terminal to a common node and thus to the input terminal 50a of the impedance matching circuit 50. The first coil 10 is connected to a reference earth via a first capacitor 12 (first capacitance). The second coil 11 is connected to the output terminal 50b via a second capacitor 13 (second capacitance). The first and second capacitors 12, 13 are adjustable components, in particular in the form of variable capacitors, the capacitance of which can be changed via stepper motors. As an alternative, solid state switches can be used to switch capacitances on and off more quickly. In particular, the plate distance between the first and second capacitors 12, 13 can be changed. The plasma ignition detection device 1 is designed to actuate the respective stepper motors accordingly. In principle, the processing unit 7 can carry out the actuation. The capacitances of the first and second capacitors 12, 13 can be adjusted independently of one another. The impedance matching circuit 50 is preferably free of further components. Of course, the position of the first coil 10 and the first capacitor 12 can also be swapped. In this case, the first capacitor 12 is arranged at the input terminal 50a of the impedance matching circuit 50 and the first coil 10 is arranged at the reference earth. In addition or as an alternative, the position of the second coil 11 and the second capacitor 13 can also be swapped. In this case, the second capacitor 13 is arranged at the input terminal 50a of the impedance matching circuit 50 and the second coil 11 is arranged at the reference earth.

In FIG. 2B, the input terminal 50a of the impedance matching circuit 50 is connected to the first capacitor 12 (first capacitance). The first capacitor 12 is connected both to the first coil 10 (first inductance) and to the second coil 11 (second inductance). This is achieved via a common node to which both the first capacitor 12 and the first and second coils 10, 11 are connected. The first coil 10 is also connected to the reference earth. The second coil 11 is connected (series circuit) to the second capacitor 13 (second capacitance). The second capacitor 13 is connected to the output terminal 50b of the impedance matching circuit 50. The position of the second coil 11 and the second capacitor 13 could also be swapped. In this case, the second capacitor 13 would be connected to the common node and the second coil 11 would be connected to the output terminal 50b of the impedance matching circuit 50. The impedance matching circuit 50 is preferably free of further components.

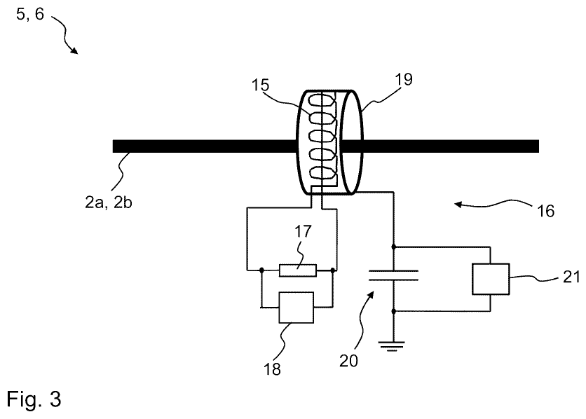

FIG. 3 shows an exemplary embodiment of a possible structure of the first and/or second measuring unit 5, 6. In this exemplary embodiment, the first and/or second measuring unit 5, 6 is designed to contactlessly measure a voltage and a current.

For this purpose, the first or second measuring unit 5, 6 comprises a current sensor 15 and a voltage sensor 16.

However, the phase relationship between current and voltage is preferably still measured so that the impedance can be calculated.

The current sensor 15 of the first and/or second measuring unit 5, 6 comprises a coil, in particular in the form of a Rogowski coil.

Both ends of the coil are preferably connected to one another via a shunt resistor 17. The voltage which drops across the shunt resistor 17 can be digitized by means of a first A/D converter (analogue-to-digital converter) 18.

The voltage sensor 16 of the first and/or second measuring unit 5, 6 is preferably designed as a capacitive voltage divider. A first capacitance 19 is formed by an electrically conductive ring 19. An electrically conductive cylinder could also be used. The corresponding first or second cable connection 2a, 2b is routed through said electrically conductive ring 19. A second capacitance 20 of the voltage sensor 16 designed as a voltage divider is connected to the reference earth. A second A/D converter 21, which is designed to detect and digitize the voltage which drops across the second capacitance 20, is connected in parallel with the second capacitance 20.

In principle, the first measuring unit 5 and the second measuring unit 6 can also be arranged or be constructed on a (common) printed circuit board. The first capacitance 19 may be formed by a coating on a first and an opposite second side of the printed circuit board. In this case, the coatings on the first and second sides are electrically connected to one another by means of vias. The first or second cable connection 2a, 2b is routed through an opening in the printed circuit board. The second capacitance 20 may be formed by a discrete component.

The current sensor 15 in the form of the coil, in particular in the form of the Rogowski coil, is spaced further apart from the first or second cable connection 2a, 2b than the first capacitance 19. The coil may also be formed on the same printed circuit board by appropriate coatings as well as vias. The coil for current measurement and the first capacitance for voltage measurement preferably pass through a common plane.

The shunt resistor 17 can also be arranged on said printed circuit board. Exactly the same also applies to the first and/or second A/D converter 18, 21.

In the event that the first and second measuring unit 5, 6 are arranged on the first cable connection 2a, these are spaced apart from one another, specifically so far that a reciprocal interfering influence is reduced to the extent that it plays only a minor role in view of the desired measurement accuracy. The first measuring unit 5 is arranged in the region of the RF generator 60 and the second measuring unit 6 is arranged in the region of the impedance matching circuit 50.

The second measuring unit 6 could also be arranged at the output terminal 50b of the impedance matching circuit 50, wherein the first measuring unit 5 is furthermore arranged in the region of the RF generator 60, so that a cable impedance of the first cable connection 2a can be detected.

The first and/or second measuring unit 5, 6 could also be in the form of directional couplers.

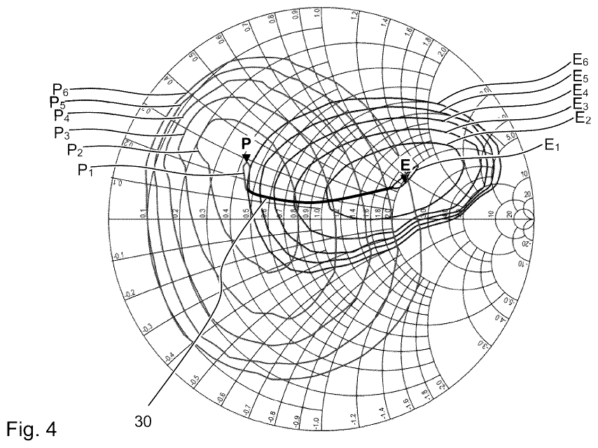

FIG. 4 shows a Smith chart illustrating how the RF generator 60 changes from maximum power to maximum efficiency depending on the target impedance value.

The Smith chart from FIG. 4 illustrates six impedance curves P₁, P₂, P₃, P₄, P₅, P₆ as examples. Any target impedance value that is on an impedance curve means that the RF generator 60 has the same output power. This means that the same output power of the RF generator 60 can be achieved with different target impedance values that are on the same impedance curve. Different impedance curves result in different output powers of the RF generator 60. The RF generator 60 generates a different output power when it sees a target impedance value that is on the impedance curve P₁ compared to a target impedance value that is on the impedance curve P₂.

FIG. 4 illustrates only six impedance curves P₁, P₂, P₃, P₄, P₅, P₆ as examples. There may also be more than six.

The Smith chart from FIG. 4 illustrates six further impedance curves E₁, E₂, E₃, E₄, E₅, E₆ as examples. Any target impedance value that is on one of said further impedance curves means that the RF generator 60 has the same efficiency. This means that the same efficiency can be achieved for the RF generator 60 with different target impedance values. Different impedance curves result in different efficiencies of the RF generator 60. The RF generator 60 is operated at a different efficiency when it sees a target impedance value that is on the impedance curve E₁ compared to a target impedance value that is on the impedance curve E₂.

The following are examples of some values to clarify the illustration.

| Power | Efficiency |
|---|---|
| P₁ = 47.7 dBm | E₁ = 91.5% |
| P₂ = 47.0 dBm | E₂ = 88.0% |
| P₃ = 46.0 dBm | E₃ = 84.0% |
| P₄ = 45.0 dBm | E₄ = 80.0% |
| P₅ = 44.0 dBm | E₅ = 76.0% |
| P₆ = 43.0 dBm | E₆ = 72.0% |

It can be seen that an efficiency of only E₆=72% is possible for the maximum possible power achievable for target impedance values that are on the impedance curve P₁. In contrast, an efficiency of E₃=84.0% is possible for a lower power P₂=47.0 dBm.

Another curve 30 is also shown. The curve 30 connects the impedance curve P₁ for the maximum possible power to the impedance curve E₁ for the maximum possible efficiency.

On the curve 30 there are different target impedance values for different target powers, wherein, for each target impedance value, the RF generator 60 provides a target power for which the efficiency has the respective maximum. If the user requires a power of P=44.5 dBm, they will move along the curve 30 to the desired target power. A corresponding target impedance value for which the efficiency has its maximum is stored for this target power. This target impedance value is then set by the impedance matching circuit 50.

In principle, a set of curves could also be drawn, wherein the respective target impedance values then result in an efficiency that is preferably at most 10% away from its maximum. The use of a set of curves would then have advantages because, for example, it is possible to use target impedance values requiring a minimum mechanical adjustment of the impedance matching circuit 50.

Preferably, the curve 30, that is to say the relationship between target power, target impedance values and optionally the efficiency, is stored in the look-up table 9. It is also clear that different profiles of the curve 30 may exist for different operating frequencies of the RF generator 60.

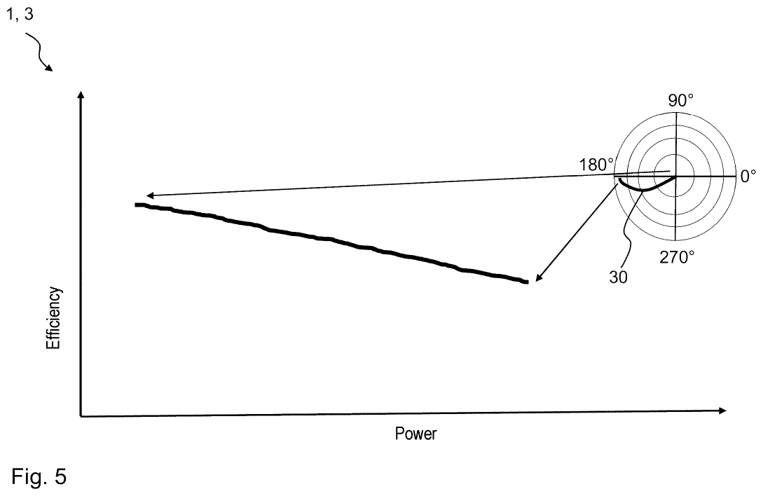

FIG. 5 shows a graph showing a profile of the efficiency for certain target powers in relation to the required target impedance values. It can be seen that the efficiency decreases as target powers increase. It is also shown which efficiency or target power can be achieved for which target impedance values. For this purpose, the curve 30 is still drawn in FIG. 5, wherein a first end of the curve 30 is associated with a maximum efficiency and wherein a second end of the curve 30 is associated with a maximum power.

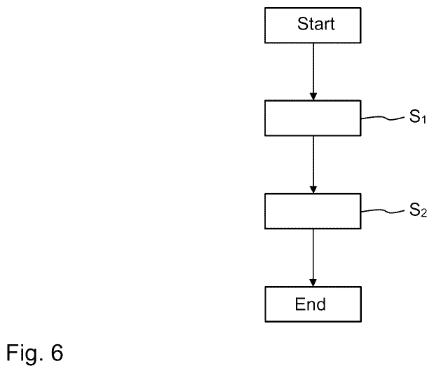

FIG. 6 shows a flowchart describing a method for actuating the impedance matching circuit 50. In the method step S₁, a target impedance value for the input terminal 50a of the impedance matching circuit 50 is determined based on a predeterminable operating frequency of the RF generator 60, a predeterminable target power of the RF generator 60 and based on model parameters of the RF generator 60. The target impedance value differs from a nominal impedance in order to thereby increase a characteristic operating value of the RF generator 60, in particular in order to thereby increase the efficiency of the RF generator 60. In the method step S₂, the determined target impedance value is set by the impedance matching circuit 50.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A control device for actuating an impedance matching circuit for a plasma generation system having an input terminal and an output terminal for connection between an RF generator and a load,
the control device is configured to use:
a predeterminable operating frequency of the RF generator;
a predetermined target power of the RF generator; and
model parameters of the RF generator;
to determine a target impedance value for the input terminal of the impedance matching circuit, wherein the target impedance value has a value different to a nominal impedance in order to increase a characteristic operating value of the RF generator, in particular an efficiency, for the predeterminable operating frequency and the predeterminable target power.

2. The control device according to claim 1, wherein:
the characteristic operating value comprises one or more of following characteristics of the RF generator:
the efficiency;
a temperature, in particular a maximum permissible temperature, in certain components;
a voltage, in particular a maximum permissible voltage, in certain components; or
a current, in particular a maximum permissible current, in certain components.

3. The control device according to claim 1, wherein:
the control device is configured to actuate the impedance matching circuit so as to set an impedance of the input terminal to the target impedance value.

4. The control device according to claim 1, wherein:
the nominal impedance is 50 ohms.

5. The control device according to claim 1, wherein:
the control device is configured to select the target impedance value for which the efficiency is improved with respect to an efficiency for the nominal impedance.

6. The control device according to claim 1, wherein:
the model parameters of the RF generator include corresponding target impedance values, for which the efficiency reaches a maximum or is at most 10% away from the maximum, for various predeterminable target powers.

7. The control device according to claim 6, wherein:
the various predeterminable target powers are on a curve or a set of curves.

8. The control device according to claim 7, wherein:
the control device is configured, for adjacent target powers on the curve or the set of curves, to store the target impedance values which, when selected in succession, require a minimum mechanical adjustment of the impedance matching circuit.

9. The control device according to claim 6, wherein:
the control device comprises a storage device, wherein the storage device has a look-up table in which corresponding target impedance values for which the efficiency reaches the maximum or is at most 10% away from the maximum are stored for the various target powers.

10. The control device according to claim 1, wherein:
the control device is configured to additionally take into account model parameters of a cable impedance of a cable connection between the RF generator and the impedance matching circuit.

11. The control device according to claim 10, wherein:
the control device is configured to load the cable impedance from a storage device; or
the control device is configured to calculate the cable impedance by a first measuring unit and a second measuring unit, wherein the first measuring unit is arranged between the RF generator and the cable connection, and wherein the second measuring unit is arranged between the cable connection and the impedance matching circuit or between the impedance matching circuit and the load.

12. The control device according to claim 1, wherein:
the control device is configured to additionally take into account model parameters of the impedance matching circuit.

13. The control device according to claim 1, wherein:
the control device comprises different model parameters for different operating frequencies of the RF generator.

14. The control device according to claim 1, wherein:
the input terminal is arranged on a housing of the impedance matching circuit.

15. The control device according to claim 1, wherein:
the RF generator is connected to the impedance matching circuit via a cable connection, wherein a first end of the cable connection is connected to the RF generator, and wherein a second end of the cable connection is connected to the impedance matching circuit, wherein the input terminal is arranged at the first end of the cable connection.

16. The control device according to claim 1, wherein:
the control device is configured, in a pulsed operation of the RF generator in which pulses with different amplitudes are generated, to determine different target impedance values for the input terminal of the impedance matching circuit for the different pulses.

17. The control device according to claim 1, wherein:
the control device is configured to determine target impedance values for the input terminal of the impedance matching circuit, wherein the target impedance values are selected such that the RF generator provides a corresponding target power for an entire envelope of a generated signal.

18. A plasma generation system having a control device according to claim 1, an RF generator, and an impedance matching circuit, wherein an output terminal of the RF generator is connected to the input terminal of the impedance matching circuit.

19. The plasma generation system according to claim 18, wherein:
the impedance matching circuit is integrated into the RF generator.

20. The plasma generation system according to claim 18, wherein:
the impedance matching circuit is connected to the RF generator via a cable connection.

21. The plasma generation system according to claim 20, wherein:
the cable connection comprises at least two cables connected in parallel in order to reduce an impedance of the cable connection.

22. The plasma generation system according to claim 20, wherein:
the control device is configured to take into account the cable impedance of the cable connection between the RF generator and the impedance matching circuit when determining the target impedance value at the input terminal of the impedance matching circuit.

23. The plasma generation system according to claim 22, wherein:
the control device is configured to take into account the cable impedance of the cable connection between the RF generator and the impedance matching circuit and to continuously redetermine the cable impedance during operation of the plasma generation system.

24. The plasma generation system according to claim 20, further comprising:
a first measuring unit and a second measuring unit;
wherein the control device is configured to calculate the cable impedance of the cable connection by the first measuring unit and the second measuring unit, wherein the first measuring unit:
is arranged between the RF generator and the cable connection; and/or
in the region of the output terminal of the RF generator; and
wherein the second measuring unit:
is arranged between the cable connection and the impedance matching circuit and/or in the region of the input terminal of the impedance matching circuit; or
between the impedance matching circuit and the load.

25. The plasma generation system according to claim 24, wherein:
the first measuring unit has a directional coupler and/or the second measuring unit has a directional coupler; and/or
the first measuring unit comprises a current sensor and a voltage sensor and/or the second measuring unit comprises a current sensor and a voltage sensor.

26. The plasma generation system according to claim 25, wherein:
the voltage sensor of the first measuring unit has a capacitive voltage divider, wherein a first capacitance is formed by an electrically conductive ring or cylinder, through which the cable connection is routed in a region of the output terminal of the RF generator and the impedance matching circuit;
and
the current sensor of the first measuring unit has a coil arranged around the conductive ring or cylinder;
and/or
the voltage sensor of the second measuring unit has a capacitive voltage divider, wherein a first capacitance is formed by an electrically conductive ring or cylinder, through which:
the cable connection is routed in a region of the input terminal of the impedance matching circuit; or
the cable connection is routed between the impedance matching circuit and the load;
and
the current sensor of the second measuring unit has a coil arranged around the conductive ring or cylinder.

27. The plasma generation system according to claim 18, wherein:
the control device is configured to change the power of the RF generator, by changing an input power of an amplifier of the RF generator and/or by changing a supply voltage of an amplifier of the RF generator.

28. The plasma generation system according to claim 18, wherein:
the impedance matching circuit comprises one or more capacitances, wherein a value of at least one capacitance is changeable during operation.

29. A method for actuating an impedance matching circuit for a plasma generation system comprising an input terminal connected to an output terminal of an RF generator and an output terminal connected to an input of a load, wherein the method is for setting an input impedance at the input terminal with varying output impedance at the output terminal, the method comprising:
determining a target impedance value for the input terminal based on:
a predeterminable operating frequency of the RF generator;
a predetermined target power of the RF generator; and
model parameters of the RF generator;
wherein the target impedance value has a value different to a nominal impedance in order to increase a characteristic operating value of the RF generator, in particular an efficiency, for the predeterminable operating frequency and the predeterminable target power.
